(19) United States
(12) Patent Application Publication
(10) Pub. No.: US 2026/0047472 A1
(43) Pub. Date: Feb. 12, 2026

(54) STRUCTURES AND METHODS FOR BONDING DIES

(71) Applicant: ADEIA SEMICONDUCTOR BONDING TECHNOLOGIES INC., San Jose, CA (US)

(72) Inventors: Oliver ZHAO, Sunnyvale, CA (US); Thomas WORKMAN, San Jose, CA (US); Guilian GAO, Campbell, CA (US); Gaius Gillman FOUNTAIN, JR., Youngsville, NC (US)

(21) Appl. No.: 18/934,145

(22) Filed: Oct. 31, 2024

Related U.S. Application Data
(60) Provisional application No. 63/680,499, filed on Aug. 7, 2024.

(51) Int. Cl. H01L 23/00; H01L 25/065

(52) U.S. Cl. CPC H01L 24/06; H01L 24/08; H01L 24/80; H01L 25/0657; H01L 2224/0603; H01L 2224/06179; H01L 2224/06515; H01L 2224/08145; H01L 2224/80139; H01L 2224/80895; H01L 2224/80896; H01L 2225/06568

(57) ABSTRACT

Disclosed is a bonded structure including a first microelectronic structure with a first bonding surface and a second microelectronic structure with a second bonding surface directly bonded to the first bonding surface. The first microelectronic structure includes at least one cavity a through the first bonding surface. The second microelectronic structure includes at least one protrusion extending above the second bonding surface. The at least one protrusion of the second microelectronic structure extends within the at least one cavity of the first microelectronic structure without reaching a bottom of the at least one cavity.

### BACKGROUND

### Field

The field relates to methods and structures for bonding dies, such as semiconductor and other microelectronic dies.

### Description of the Related Art

Microelectronic bonded structures can be assembled for packaging by bonding a plurality (a few, tens, hundreds, or more) of dies onto a host substrate (e.g., a larger die, a wafer, an interposer, etc.). Direct bonding generally, and hybrid bonding more specifically, can advantageously provide robust connections among the elements being bonded, and facilitate greater density of connections. However, manufacturing yield remains an issue for bonding microelectronic elements.

### BRIEF DESCRIPTION OF THE DRAWINGS

The detailed description is set forth with reference to the accompanying figures.

For this discussion, the devices and systems illustrated in the figures are shown as having a multiplicity of components. Various implementations of devices and/or systems, as described herein, may include fewer components and remain within the scope of the disclosure. Alternatively, other implementations of devices and/or systems may include additional components, or various combinations of the described components, and remain within the scope of the disclosure.

These aspects and others will be apparent from the following description of preferred embodiments and the accompanying drawings, which are meant to illustrate and not to limit the invention, wherein:

FIG. 1A is a schematic side sectional view of two elements before being directly bonded, according to an embodiment.

FIG. 1B is a schematic side sectional view of the two elements of FIG. 1A after being directly bonded, according to an embodiment.

FIG. 2A is a schematic plan view of a bonded structure, showing the consequences of a misaligned die.

FIG. 2B is a schematic side sectional view of the bonded structure of FIG. 2A.

FIG. 3A is a schematic plan view of a bonded structure, showing alignment guide regions, according to an embodiment.

FIGS. 3B-3C are schematic side sectional views of alignment guide regions, according to various embodiments.

FIG. 4 is a schematic side sectional view of an alignment guide region, according to an embodiment.

FIG. 5A is a schematic side sectional view of a bonded structure in which a protrusion of a first component is engaged with a cavity of a second component, according to an embodiment.

FIG. 5B is a schematic side sectional view of an intended bonded structure in which the protrusion of a first component is grossly misaligned with a cavity of a second component, according to an embodiment.

FIGS. 6A-6D present a series of schematic side sectional views that show two methods by which a microelectronic component can be formed to have a protrusion deposited thereon, according to an embodiment.

FIGS. 7A-7B present a series of schematic side sectional views that show a transfer method by which a microelectronic component can be formed to have a protrusion attached thereto, according to an embodiment.

FIGS. 8A-8D present a series of schematic side sectional views that show a method by which a microelectronic component can be formed to have a cavity etched from a conductive feature, according to an embodiment.

FIGS. 9A-9D present a series of schematic side sectional views that show a method by which a microelectronic component can be formed to have a cavity etched from a dielectric layer, according to an embodiment.

### DETAILED DESCRIPTION

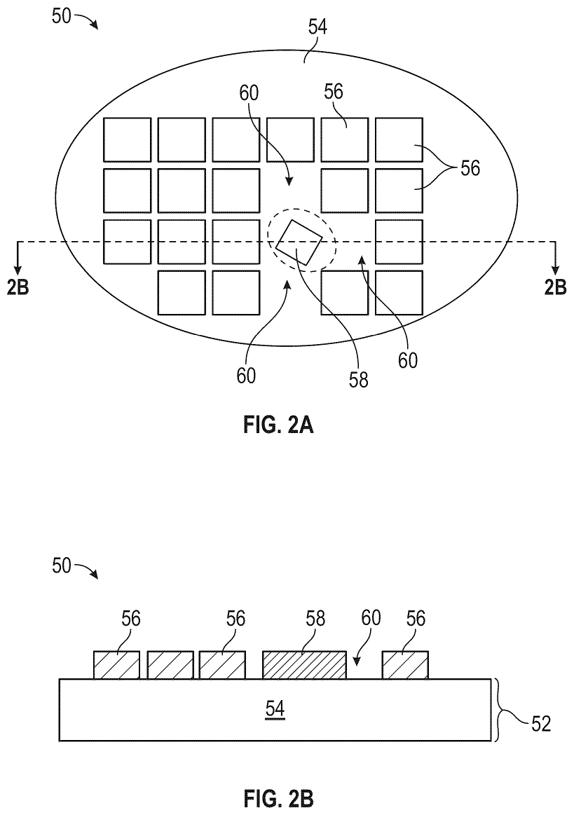

During direct or hybrid bonding operations, a die is attached to a predetermined or intended region on the surface of a prepared host or substrate. Occasionally, the attached dies may drift away from their predetermined region or site and come to rest at a location different from the intended region on the surface of the prepared substrate; thus, forming a misaligned die (e.g. a misplaced die or blocking die) on the substrate, as shown, for example, in FIGS. 2A and 2B. It will be understood that when a die is described herein as being “misaligned” or “misplaced,” those descriptors refer only to the fact that the final position of the die is different than its predetermined or intended region. Such a die can end up in a location different from its predetermined or intended region in any number of ways, including but not limited to situations in which the die is originally placed incorrectly (e.g., by a pick-and-place apparatus) due to errors in picking up the die or errors in placing the die, situations in which the die is originally placed correctly (e.g., by a pick-and-place apparatus) but drifts to a different location before coming to rest (e.g., sliding due to an air cushion, poor dielectric adhesion, or particle contamination of the bonding interface), combinations of the above, or any other situation in which the die comes to rest at a location different from its correct location. Any such die can be referred to interchangeably herein as being “misaligned” or “misplaced,” without implying any particular process by which the die reaches the incorrect location.

Misplacement of a die on a substrate can negatively affect the yield of the affected site and may also negatively affect neighboring sites. For example, a die may have small features (e.g., conductive features) designed to precisely line up with corresponding features of the substrate to which it is being bonded. Misplacement of the die can cause the features to be out of alignment with the corresponding features of the substrate. This can cause the misplaced die to not function as intended. Additionally, the misplacement of a die can cause neighboring dies to not work as intended. When a die is misplaced on a substrate, the misplaced die can interfere with (e.g., block) the placement and function of neighboring dies. A misplaced or misaligned die that interferes with or blocks the placement and/or function of neighboring dies can be referred to as a “blocking die.” In this way, one misplacement can cause undesirable yield loss amongst other dies. Preventing a misplaced die on a substrate from interfering with the placement of neighboring dies, e.g., preventing or limiting movement of misplaced dies, can improve manufacturing yield. This problem is particularly acute for direct bonding, where dielectric materials sufficiently prepared (e.g., sufficiently planarized) for direct bonding can begin to bond to a host element (e.g., die, wafer, interposer, dielectric surface, flat panel surface) once placed in contact with the host element at room temperature, even before any further processing, thus preventing any correction of misplacement.

Various embodiments disclosed herein relate to directly bonded structures in which two or more elements can be directly bonded to one another without an intervening adhesive. Such processes and structures are referred to herein as “direct bonding” processes or “directly bonded” structures. Direct bonding can involve bonding of one material on one element and one material on the other element (also referred to as “uniform” direct bond herein), where the materials on the different elements need not be the same, without traditional adhesive materials. Direct bonding can also involve bonding of multiple materials on one element to multiple materials on the other element (e.g., hybrid bonding).

In some implementations (not illustrated), each bonding layer has one material. In these uniform direct bonding processes, only one material on each element is directly bonded. Example uniform direct bonding processes include the ZIBOND® techniques commercially available from Adeia of San Jose, CA. The materials of opposing bonding layers on the different elements can be the same or different, and may comprise elemental or compound materials. For example, in some embodiments, nonconductive bonding layers can be blanket deposited over the base substrate portions without being patterned with conductive features (e.g., without pads). In other embodiments, the bonding layers can be patterned on one or both elements, and can be the same or different from one another, but one material from each element is directly bonded without adhesive across surfaces of the elements (or across the surface of the smaller element if the elements are differently-sized). In another implementation of uniform direct bonding, one or both of the nonconductive bonding layers may include one or more conductive features, but the conductive features are not involved in the bonding. For example, in some implementations, opposing nonconductive bonding layers can be uniformly directly bonded to one another, and through substrate vias (TSVs) can be subsequently formed through one element after bonding to provide electrical communication to the other element.

In various embodiments, the bonding layers 108a and/or 108b can comprise a non-conductive material such as a dielectric material or an undoped semiconductor material, such as undoped silicon, which may include native oxide. Suitable dielectric bonding surface or materials for direct bonding include but are not limited to inorganic dielectrics, such as silicon oxide, silicon nitride, or silicon oxynitride, or can include carbon, such as silicon carbide, silicon oxycarbonitride, low K dielectric materials, SiCOH dielectrics, silicon carbonitride or diamond-like carbon or a material comprising a diamond surface. Such carbon-containing ceramic materials can be considered inorganic, despite the inclusion of carbon. In some embodiments, the dielectric materials at the bonding surface do not comprise polymer materials, such as epoxy (e.g., epoxy adhesives, cured epoxies, or epoxy composites such as FR-4 materials), resin or molding materials.

In other embodiments, the bonding layers can comprise an electrically conductive material, such as a deposited conductive oxide material, e.g., indium tin oxide (ITO), as disclosed in U.S. patent application Ser. No. 18/391,173, filed Dec. 20, 2023, the entire contents of which is incorporated by reference herein in its entirety for providing examples of conductive bonding layers without shorting contacts through the interface.

In direct bonding, first and second elements can be directly bonded to one another without an adhesive, which is different from a deposition process and results in a structurally different interface compared to that produced by deposition. In one application, a width of the first element in the bonded structure is similar to a width of the second element. In some other embodiments, a width of the first element in the bonded structure is different from a width of the second element. The width or area of the larger element in the bonded structure may be at least 10% larger than the width or area of the smaller element. Further, the interface between directly bonded structures, unlike the interface beneath deposited layers, can include a defect region in which nanometer-scale voids (nanovoids) are present. The nanovoids may be formed due to activation of one or both of the bonding surfaces (e.g., exposure to a plasma, explained below).

The bond interface between non-conductive bonding surfaces can include a higher concentration of materials from the activation and/or last chemical treatment processes compared to the bulk of the bonding layers. For example, in embodiments that utilize a nitrogen plasma for activation, a nitrogen concentration peak can be formed at the bond interface. In some embodiments, the nitrogen concentration peak may be detectable using secondary ion mass spectroscopy (SIMS) techniques. In various embodiments, for example, a nitrogen termination treatment (e.g., exposing the bonding surface to a nitrogen-containing plasma) can replace OH groups of a hydrolyzed (OH-terminated) surface with NH₂ molecules, yielding a nitrogen-terminated surface. In embodiments that utilize an oxygen plasma for activation, an oxygen concentration peak can be formed at the bond interface between non-conductive bonding surfaces. In some embodiments, the bond interface can comprise silicon oxynitride, silicon oxycarbonitride, or silicon carbonitride. The direct bond can comprise a covalent bond, which is stronger than van Der Waals bonds. The bonding layers can also comprise polished surfaces that are planarized to a high degree of smoothness.

In direct bonding processes, such as uniform direct bonding and hybrid bonding, two elements are bonded together without an intervening adhesive. In non-direct bonding processes that utilize an adhesive, an intervening material is typically applied to one or both elements to effectuate a physical connection between the elements. For example, in some adhesive-based processes, a flowable adhesive (e.g., an organic adhesive, such as an epoxy), which can include conductive filler materials, can be applied to one or both elements and cured to form the physical (rather than chemical or covalent) connection between elements. Some organic adhesives lack strong chemical or covalent bonds with either element. In such processes, the connections between the elements are weak and/or readily reversed, such as by reheating or defluxing.

By contrast, direct bonding processes join two elements by forming strong chemical bonds (e.g., covalent bonds) between opposing nonconductive materials. For example, in direct bonding processes between nonconductive materials, one or both nonconductive surfaces of the two elements are planarized and chemically prepared (e.g., activated and/or terminated) such that when the elements are brought into contact, strong chemical bonds (e.g., covalent bonds) are formed, which are stronger than Van der Waals or hydrogen bonds. In some implementations (e.g., between opposing dielectric surfaces, such as opposing silicon oxide surfaces), the chemical bonds can occur spontaneously at room temperature upon being brought into contact. In some implementations, the chemical bonds between opposing non-conductive materials can be strengthened after annealing the elements.

As noted above, hybrid bonding is a species of direct bonding in which both non-conductive features directly bond to non-conductive features, and conductive features directly bond to conductive features of the elements being bonded. The non-conductive bonding materials and interface can be as described above, while the conductive bond can be formed, for example, as a direct metal-to-metal connection. In conventional metal bonding processes, a fusible metal alloy (e.g., solder) can be provided between the conductors of two elements, heated to melt the alloy, and cooled to form the connection between the two elements. The resulting bond often evinces sharp interfaces with conductors from both elements, and is subject to reversal by reheating. By way of contrast, direct metal bonding as employed in hybrid bonding does not require melting or an intermediate fusible metal alloy, and can result in strong mechanical and electrical connections, often demonstrating interdiffusion of the bonded conductive features with grain growth across the bonding interface between the elements, even without the much higher temperatures and pressures of thermocompression bonding.

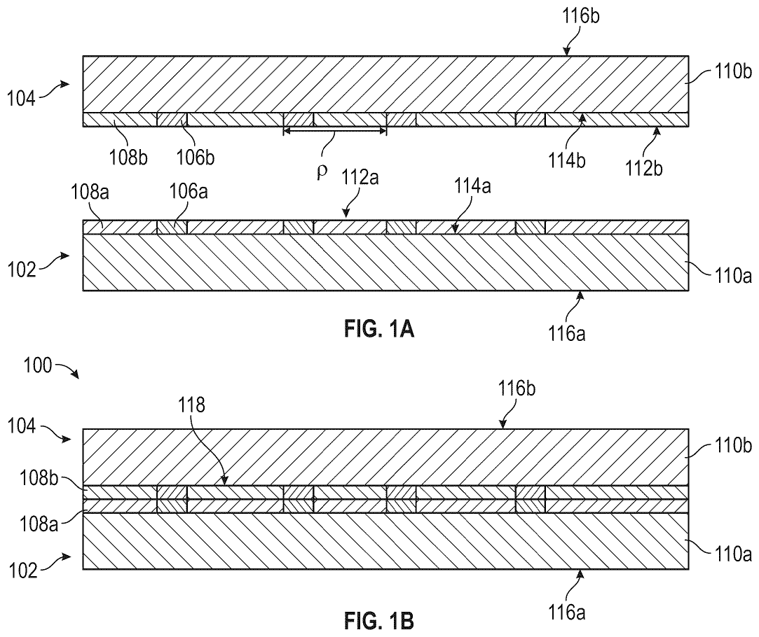

FIGS. 1A and 1B schematically illustrate cross-sectional side views of first and second elements 102, 104 prior to and after, respectively, a process for forming a directly bonded structure, and more particularly a hybrid bonded structure, according to some embodiments. In FIG. 1B, a bonded structure 100 comprises the first and second elements 102 and 104 that are directly bonded to one another at a bond interface 118 without an intervening adhesive. Conductive features 106a of a first element 102 may be electrically connected to corresponding conductive features 106b of a second element 104. In the illustrated hybrid bonded structure 100, the conductive features 106a are directly bonded to the corresponding conductive features 106b without intervening solder or conductive adhesive.

The conductive features 106a and 106b of the illustrated embodiment are embedded in, and can be considered part of, a first bonding layer 108a of the first element 102 and a second bonding layer 108b of the second element 104, respectively. Field regions of the bonding layers 108a, 108b extend between and partially or fully surround the conductive features 106a, 106b. The bonding layers 108a, 108b can comprise layers of non-conductive materials suitable for direct bonding, as described above, and the field regions are directly bonded to one another without an adhesive. The non-conductive bonding layers 108a, 108b can be disposed on respective front sides 114a, 114b of base substrate portions 110a, 110b.

The first and second elements 102, 104 can comprise microelectronic elements, such as semiconductor elements, including, for example, integrated device dies, wafers, passive devices, discrete active devices such as power switches, MEMS, etc. In some embodiments, the base substrate portion can comprise a device portion, such as a bulk semiconductor (e.g., silicon) portion of the elements 102, 104, and back-end-of-line (BEOL) interconnect layers over such semiconductor portions. The bonding layers 108a, 108b can be provided as part of such BEOL layers during device fabrication, as part of redistribution layers (RDL), or as specific bonding layers added to existing devices, with bond pads extending from underlying contacts. Active devices and/or circuitry can be patterned and/or otherwise disposed in or on the base substrate portions 110a, 110b, and can electrically communicate with at least some of the conductive features 106a, 106b. Active devices and/or circuitry can be disposed at or near the front sides 114a, 114b of the base substrate portions 110a, 110b, and/or at or near opposite backsides 116a, 116b of the base substrate portions 110a, 110b. In other embodiments, the base substrate portions 110a, 110b may not include active circuitry, but may instead comprise dummy substrates, passive interposers, passive optical elements (e.g., glass substrates, gratings, lenses), etc. The bonding layers 108a, 108b are shown as being provided on the front sides of the elements, but similar bonding layers can be additionally or alternatively provided on the back sides of the elements.

In some embodiments, the base substrate portions 110a, 110b can have significantly different coefficients of thermal expansion (CTEs), and bonding elements that include such different based substrate portions can form a heterogenous bonded structure. The CTE difference between the base substrate portions 110a and 110b, and particularly between bulk semiconductor (typically single crystal) portions of the base substrate portions 110a, 110b, can be greater than 5 ppm/° C. or greater than 10 ppm/° C. For example, the CTE difference between the base substrate portions 110a and 110b can be in a range of 5 ppm/° C. to 100 ppm/° C., 5 ppm/° C. to 40 ppm/° C., 10 ppm/° C. to 100 ppm/° C., or 10 ppm/° C. to 40 ppm/° C.

In some embodiments, one of the base substrate portions 110a, 110b can comprise optoelectronic single crystal materials, including perovskite materials, that are useful for optical piezoelectric or pyroelectric applications, and the other of the base substrate portions 110a, 110b comprises a more conventional substrate material. For example, one of the base substrate portions 110a, 110b comprises lithium tantalate (LiTaO₃) or lithium niobate (LiNbO₃), and the other one of the base substrate portions 110a, 110b comprises silicon (Si), quartz, fused silica glass, sapphire, or a glass. In other embodiments, one of the base substrate portions 110a, 110b comprises a III-V single semiconductor material, such as gallium arsenide (GaAs) or gallium nitride (GaN), and the other one of the base substrate portions 110a, 110b can comprise a non-III-V semiconductor material, such as silicon (Si), or can comprise other materials with similar CTE, such as quartz, fused silica glass, sapphire, or a glass. In still other embodiments, one of the base substrate portions 110a, 110b comprises a semiconductor material and the other of the base substrate portions 110a, 110b comprises a packaging material, such as a glass, organic or ceramic substrate.

In some arrangements, the first element 102 can comprise a singulated element, such as a singulated integrated device die. In other arrangements, the first element 102 can comprise a carrier or substrate (e.g., a semiconductor wafer) that includes a plurality (e.g., tens, hundreds, or more) of device regions that, when singulated, forms a plurality of integrated device dies, though in other embodiments such a carrier can be a package substrate or a passive or active interposer. Similarly, the second element 104 can comprise a singulated element, such as a singulated integrated device die. In other arrangements, the second element 104 can comprise a carrier or substrate (e.g., a semiconductor wafer). The embodiments disclosed herein can accordingly apply to wafer-to-wafer (W2W), die-to-die (D2D), or die-to-wafer (D2W) bonding processes. In W2W processes, two or more wafers can be directly bonded to one another (e.g., direct hybrid bonded) and singulated using a suitable singulation process. After singulation, side edges of the singulated structure (e.g., the side edges of the two bonded elements) can be substantially flush (substantially aligned x-y dimensions) and/or the edges of the bonding interfaces for both bonded and singulated elements can be coextensive, and may include markings indicative of the common singulation process for the bonded structure (e.g., saw markings if a saw singulation process is used).

While only two elements 102, 104 are shown, any suitable number of elements can be stacked in the bonded structure 100. For example, a third element (not shown) can be stacked on the second element 104, a fourth element (not shown) can be stacked on the third element, and so forth. In such implementations, through substrate vias (TSVs) can be formed to provide vertical electrical communication between and/or among the vertically-stacked elements. Additionally or alternatively, one or more additional elements (not shown) can be stacked laterally adjacent one another along the first element 102. In some embodiments, a laterally stacked additional element may be smaller than the second element. In some embodiments, the bonded structure can be encapsulated with an insulating material, such as an inorganic dielectric (e.g., silicon oxide, silicon nitride, silicon oxynitrocarbide, etc.). One or more insulating layers can be provided over the bonded structure. For example, in some implementations, a first insulating layer can be conformally deposited over the bonded structure, and a second insulating layer (which may include be the same material as the first insulating layer, or a different material) can be provided over the first insulating layer.

To effectuate direct bonding between the bonding layers 108a, 108b, the bonding layers 108a, 108b can be prepared for direct bonding. Non-conductive bonding surfaces 112a, 112b at the upper or exterior surfaces of the bonding layers 108a, 108b can be prepared for direct bonding by polishing, for example, by chemical mechanical polishing (CMP). The roughness of the polished bonding surfaces 112a, 112b can be less than 30 Å rms. For example, the roughness of the bonding surfaces 112a and 112b can be in a range of about 0.1 Å rms to 15 Å rms, 0.5 Å rms to 10 Å rms, or 1 Å rms to 5 Å rms. Polishing can also be tuned to leave the conductive features 106a, 106b recessed relative to the field regions of the bonding layers 108a, 108b.

Preparation for direct bonding can also include cleaning and exposing one or both of the bonding surfaces 112a, 112b to a plasma and/or etchants to activate at least one of the surfaces 112a, 112b. In some embodiments, one or both of the surfaces 112a, 112b can be terminated with a species after activation or during activation (e.g., during the plasma and/or etch processes). Without being limited by theory, in some embodiments, the activation process can be performed to break chemical bonds at the bonding surface(s) 112a, 112b, and the termination process can provide additional chemical species at the bonding surface(s) 112a, 112b that alters the chemical bond and/or improves the bonding energy during direct bonding. In some embodiments, the activation and termination are provided in the same step, e.g., a plasma to activate and terminate the surface(s) 112a, 112b. In other embodiments, one or both of the bonding surfaces 112a, 112b can be terminated in a separate treatment to provide the additional species for direct bonding. In various embodiments, the terminating species can comprise nitrogen. For example, in some embodiments, the bonding surface(s) 112a, 112b can be exposed to a nitrogen-containing plasma. Other terminating species can be suitable for improving bonding energy, depending upon the materials of the bonding surfaces 112a, 112b. Further, in some embodiments, the bonding surface(s) 112a, 112b can be exposed to fluorine. For example, there may be one or multiple fluorine concentration peaks at or near a bond interface 118 between the first and second elements 102, 104. Typically, fluorine concentration peaks occur at interfaces between material layers. Additional examples of activation and/or termination treatments may be found in U.S. Pat. No. 9,391,143 at Col. 5, line 55 to Col. 7, line 3; Col. 8, line 52 to Col. 9, line 45; Col. 10, lines 24-36; Col. 11, lines 24-32, 42-47, 52-55, and 60-64; Col. 12, lines 3-14, 31-33, and 55-67; Col. 14, lines 38-40 and 44-50; and U.S. Pat. No. 10,434,749 at Col. 4, lines 41-50; Col. 5, lines 7-22, 39, 55-61; Col. 8, lines 25-31, 35-40, and 49-56; and Col. 12, lines 46-61, the activation and termination teachings of which are incorporated by reference herein.

Thus, in the directly bonded structure 100, the bond interface 118 between two non-conductive materials (e.g., the bonding layers 108a, 108b) can comprise a very smooth interface with higher nitrogen (or other terminating species) content and/or fluorine concentration peaks at the bond interface 118. In some embodiments, the nitrogen and/or fluorine concentration peaks may be detected using various types of inspection techniques, such as SIMS techniques. The polished bonding surfaces 112a and 112b can be slightly rougher (e.g., about 1 Å rms to 30 Å rms, 3 Å rms to 20 Å rms, or possibly rougher) after an activation process. In some embodiments, activation and/or termination can result in slightly smoother surfaces prior to bonding, such as where a plasma treatment preferentially erodes high points on the bonding surface.

The non-conductive bonding layers 108a and 108b can be directly bonded to one another without an adhesive. In some embodiments, the elements 102, 104 are brought together at room temperature, without the need for application of a voltage, and without the need for application of external pressure or force beyond that used to initiate contact between the two elements 102, 104. Contact alone can cause direct bonding between the non-conductive surfaces of the bonding layers 108a, 108b (e.g., covalent dielectric bonding). Subsequent annealing of the bonded structure 100 can cause the conductive features 106a, 106b to directly bond.

In some embodiments, prior to direct bonding, the conductive features 106a, 106b are recessed relative to the surrounding field regions, such that a total gap between opposing contacts after dielectric bonding and prior to anneal is less than 15 nm, or less than 10 nm. Because the recess depths for the conductive features 106a and 106b can vary across each element, due to process variation, the noted gap can represent a maximum or an average gap between corresponding conductive features 106a, 106b of two joined elements (prior to anneal). Upon annealing, the conductive features 106a and 106b can expand and contact one another to form a metal-to-metal direct bond.

During annealing, the conductive features 106a, 106b (e.g., metallic material) can expand while the direct bonds between surrounding non-conductive materials of the bonding layers 108a, 108b resist separation of the elements, such that the thermal expansion increases the internal contact pressure between the opposing conductive features. Annealing can also cause metallic grain growth across the bonding interface, such that grains from one element migrate across the bonding interface at least partially into the other element, and vice versa. Thus, in some hybrid bonding embodiments, opposing conductive materials are joined without heating above the conductive materials'melting temperature, such that bonds can form with lower anneal temperatures compared to soldering or thermocompression bonding.

In various embodiments, the conductive features 106a, 106b can comprise discrete pads, contacts, electrodes, or traces at least partially embedded in the non-conductive field regions of the bonding layers 108a, 108b. In some embodiments, the conductive features 106a, 106b can comprise exposed contact surfaces of TSVs (e.g., through silicon vias).

As noted above, in some embodiments, in the elements 102, 104 of FIG. 1A prior to direct bonding, portions of the respective conductive features 106a and 106b can be recessed below the non-conductive bonding surfaces 112a and 112b, for example, recessed by less than 30 nm, less than 20 nm, less than 15 nm, or less than 10 nm, for example, recessed in a range of 2 nm to 20 nm, or in a range of 4 nm to 10 nm. Due to process variation, both dielectric thickness and conductor recess depths can vary across an element. Accordingly, the above recess depth ranges may apply to individual conductive features 106a, 106b or to average depths of the recesses relative to local non-conductive field regions. Even for an individual conductive feature 106a, 106b, the vertical recess can vary across the feature, and so can be measured at or near the lateral middle or center of the cavity in which a given conductive feature 106a, 106b is formed, or can be measured at the sides of the cavity.

Beneficially, the use of hybrid bonding techniques (such as Direct Bond Interconnect, or DBI®, techniques commercially available from Adeia of San Jose, CA) can enable high density of connections between conductive features 106a, 106b across the direct bond interface 118 (e.g., small or fine pitches for regular arrays).

In some embodiments, a pitch p of the conductive features 106a, 106b, such as conductive traces embedded in the bonding surface of one of the bonded elements, may be less than 40 μm, less than 20 μm, less than 10 μm, less than 5 μm, less than 2 μm, or even less than 1 μm. For some applications, the ratio of the pitch of the conductive features 106a and 106b to one of the lateral dimensions (e.g., a diameter) of the bonding pad is less than 20, or less than 10, or less than 5, or less than 3 and sometimes desirably less than 2. In various embodiments, the conductive features 106a and 106b and/or traces can comprise copper or copper alloys, although other metals may be suitable, such as nickel, aluminum, or alloys thereof. The conductive features disclosed herein, such as the conductive features 106a and 106b, can comprise fine-grain metal (e.g., a fine-grain copper). Further, a major lateral dimension (e.g., a pad diameter) can be small as well, e.g., in a range of about 0.25 μm to 30 μm, in a range of about 0.25 μm to 5 μm, or in a range of about 0.5 μm to 5 μm.

For hybrid bonded elements 102, 104, as shown, the orientations of one or more conductive features 106a, 106b from opposite elements can be opposite to one another. As is known in the art, conductive features in general can be formed with close to vertical sidewalls, particularly where directional reactive ion etching (RIE) defines the conductor sidewalls either directly through etching the conductive material or indirectly through etching surrounding insulators in damascene processes. However, some slight taper to the conductor sidewalls can be present, wherein the conductor becomes narrower farther away from the surface initially exposed to the etch. The taper can be even more pronounced when the conductive sidewall is defined directly or indirectly with isotropic wet or dry etching. In the illustrated embodiment, at least one conductive feature 106b in the bonding layer 108b (and/or at least one internal conductive feature, such as a BEOL feature) of the upper element 104 may be tapered or narrowed upwardly, away from the bonding surface 112b. By way of contrast, at least one conductive feature 106a in the bonding layer 108a (and/or at least one internal conductive feature, such as a BEOL feature) of the lower element 102 may be tapered or narrowed downwardly, away from the bonding surface 112a. Similarly, any bonding layers (not shown) on the backsides 116a, 116b of the elements 102, 104 may taper or narrow away from the backsides, with an opposite taper orientation relative to front side conductive features 106a, 106b of the same element.

As described above, in an anneal phase of hybrid bonding, the conductive features 106a, 106b can expand and contact one another to form a metal-to-metal direct bond. In some embodiments, the materials of the conductive features 106a, 106b of opposite elements 102, 104 can interdiffuse during the annealing process. In some embodiments, metal grains grow into each other across the bond interface 118. In some embodiments, the metal is or includes copper, which can have grains oriented along the 111 crystal plane for improved copper diffusion across the bond interface 118. In some embodiments, the conductive features 106a and 106b may include nanotwinned copper grain structure, which can aid in merging the conductive features during anneal. There is substantially no gap between the non-conductive bonding layers 108a and 108b at or near the bonded conductive features 106a and 106b. In some embodiments, a barrier layer may be provided under and/or laterally surrounding the conductive features 106a and 106b (e.g., which may include copper). In other embodiments, however, there may be no barrier layer under the conductive features 106a and 106b.

FIGS. 2A-2B depict a bonded structure 50 comprising a microelectronic structure 52, including a substrate 54, and a plurality of dies (e.g., 56) disposed (e.g., directly bonded) thereon. Each die 56 can represent a microelectronic structure or device that has been singulated or “diced” from a larger substrate, panel or web of manufactured devices. For example, each die can represent an individual active or passive device or a circuit of multiple connected devices, such as a capacitor, inductor, resistor, transistor, MEMS device, integrated circuit, optical elements, etc. The substrate 54 can represent, for example, a wafer or flat panel having a plurality of similar such devices (e.g., integrated circuits) formed therein, prior to singulation. In other arrangements, the substrate 54 can represent a larger die, interposer, etc.

FIG. 2A depicts an overhead plan view of the bonded structure 50, and FIG. 2B depicts a side sectional view of the bonded structure 50 shown in FIG. 2A, along lines 2B-2B. FIGS. 2A and 2B depict a misaligned die 58 that can block dies in adjacent locations. The substrate 54 has an array of die regions, where dies 56 are intended to be placed. Many of the dies 56 are properly attached on their respective die regions, forming an array or grid. But the misaligned die 58 is depicted as rotated and/or translated and/or having otherwise drifted away from its intended position or die region in the array of the other dies 56. The misalignment of the misaligned die 58 can have any of a number of causes, such as slippage on a cushion of air during placement of the die, slippage during release of the die from the pick-and-place apparatus, other errors in pick up or placement of the die, poor dielectric adhesion, particle contamination at the bond interface, etc. The misalignment of misaligned die 58 can cause the misaligned die 58 to not function properly, for example, if the misalignment causes features of the die 58 to not properly align with corresponding features of the substrate 54. Additionally, the misalignment of misaligned die 58 can cause the misaligned die 58 to block or otherwise interfere with the placement of neighboring dies. Such interference can cause neighboring predetermined die regions of the substrate to be, for example, skipped, as depicted as skipped die regions 60. A drifted die—as shown by the incorrect location of the misaligned die 58—can cause errors in the placement of other dies—as shown by skipped die regions 60, creating a zone or region of condemned predetermined sites or regions around misaligned die 58. The errors in the placement of die or dies in the skipped die regions 60 represent a reduction of manufacturing yield. In the schematic of FIG. 2A, one manufacturing error (the misaligned die 58) leads to a reduction of yield by four (one misaligned die 58 and three skipped die regions 60). In embodiments where multiple die stacking is contemplated, known good dies cannot be stacked over the misaligned die 58 nor over the condemned spaces around the misaligned die 58 (e.g., skipped die regions 60). The loss of die stacking on the misaligned die 58 and adjacent condemned predetermined sites or regions (e.g., skipped die regions 60) can further aggravate the yield losses on the substrate 54. Methods and structures described herein can limit the yield loss from die misalignment.

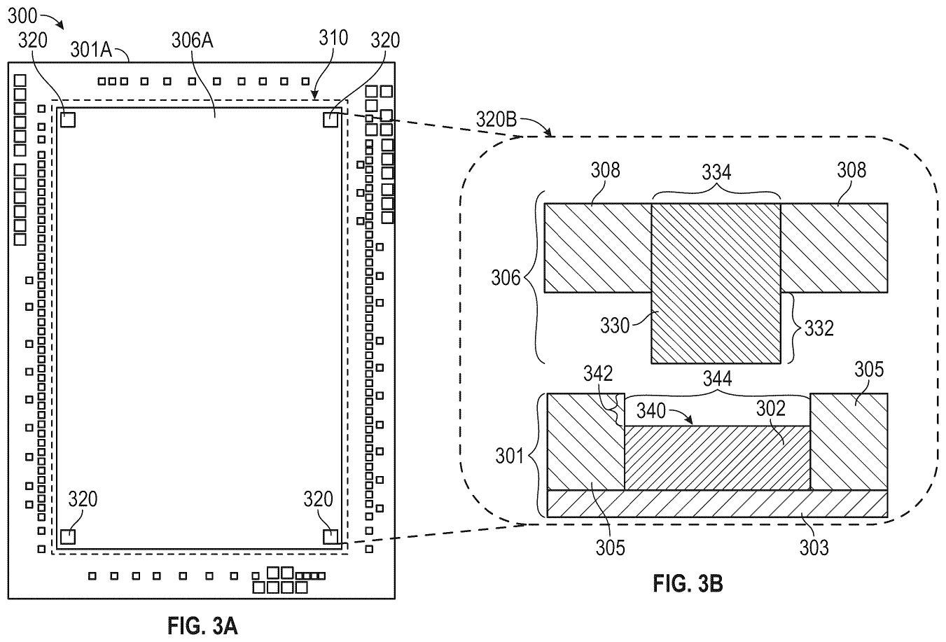

FIGS. 3A-9D illustrate and describe various embodiments that can alleviate the issues described above with respect to FIGS. 2A-2B, and can have benefits in preventing misaligned dies from interfering with neighboring dies. Additionally, the concepts described in these embodiments can also prevent a misaligned die or substrate from bonding in the wrong location, thus allowing re-use of the misaligned die or substrate itself, further reducing yield loss. Furthermore, the concepts described herein can be apply to D2D, D2W and W2W bonding.

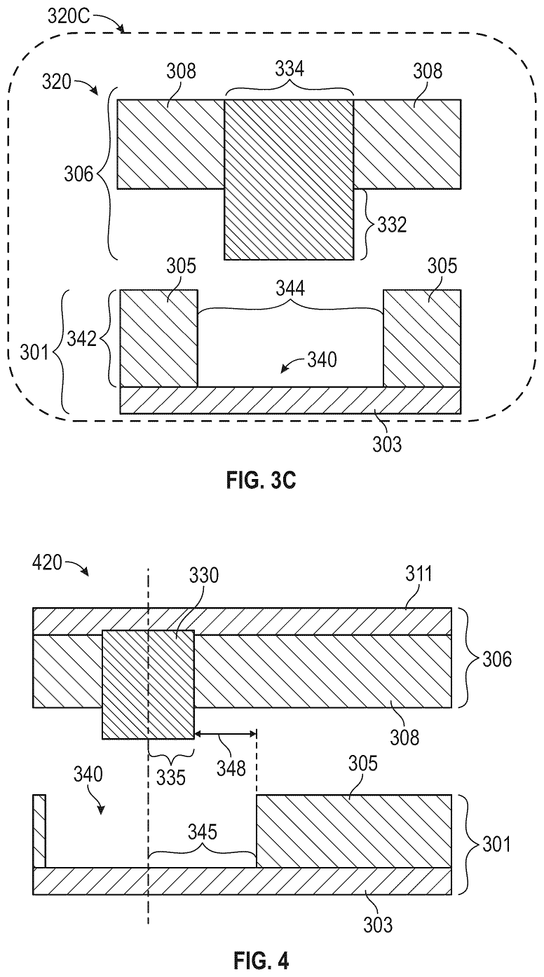

In general, the embodiments provide a protrusion, key, or pillar (e.g., protrusion 330 shown in FIGS. 3B-5B and 6C-7B), on a first substrate, and a corresponding cavity, hole, or recess (e.g., cavity 340 shown in FIGS. 3B-5B and 8C-8D, and 9C-9D) on a second substrate. Advantageously, although roughly aligned with one another in the desired bonding arrangement, the hole is larger than the key in lateral dimensions, providing tolerance to accommodate misalignment. The difference in widths (e.g., diameters or radii) and consequent areas of these features can represent the acceptable misalignment, illustrated in terms of differences in radii or half-width 335 on FIG. 4. In some arrangements, the difference in widths of the key and hole can range from about 1 μm to 30 μm, or from about 5 μm to 20 μm. More generally, the hole can have a half-width (e.g., radius) of about 120% to 300% of the half-width (e.g., radius) of the key. In one example, the hole has a radius 180% of the key radius, for arrangements in which the desired tolerance is about 80% of the pad diameter.

In terms of vertical dimensions, desirably the key or pillar does not reach the bottom of the hole or recess even after annealing for hybrid bonding. Thus, the hole depth (e.g., cavity depth 342 shown in FIGS. 3B-3C) is significantly greater than the recess of surface contacts elsewhere on the substrate, which are meant to be directly bonded by annealing after dielectric bonding. For example, the hole can be deeper than the amount of protrusion of the key by about 40-500 nm, about 50-1,500 nm, or about 50-200 nm, and the differential is illustrated as about 50 nm in the example of FIG. 3B. Example depths of the hole can be 100 nm to 10 μm, such as about 2-10 μm, and can extend through the thickness of the bonding layer as shown in FIG. 3C, which can be achieved, for example, by dry etching.

FIG. 3A depicts an overhead plan view of a bonded structure 300, according to some embodiments. The bonded structure 300 comprises a larger component 301A bonded to a smaller component 306A. The components 301A and 306A are direct bonded to each other, without an intervening adhesive, as described above. The larger component 301A has an intended bonding region 310, intended to have the smaller component 306A bonded thereto. The bonded structure 300 also has a plurality of alignment guide regions 320. The alignment guide regions 320 are within the intended bonding region 310 of the larger component 301A, and are illustrated as having 4 alignment guide regions 320 near the corners of the smaller component 306A.

In some embodiments, the larger component 301A is a microelectronic component. In some embodiments, the larger component 301A comprises a semiconductor substrate, such as silicon or a III-V compound material. In some embodiments, the larger component 301A comprises electrical components (e.g., active electrical components, passive electrical components, optical components, MEMS, etc.) and/or connections (e.g., wires, RDLs, TSVs, etc.) embedded therein or deposited thereon. In some embodiments, the larger component 301A is a wafer. In some embodiments, the larger component 301A is an interposer. In some embodiments, the larger component 301A is a die. The larger component 301A has a larger surface area or footprint than that of the smaller component 306A.

In some embodiments, the smaller component 306A is a microelectronic component. In some embodiments, the smaller component 306A comprises a semiconductor substrate, such as silicon or a III-V compound material. In some embodiments, the smaller component 306A comprises electrical components (e.g., active electrical components, passive electrical components, optical components, MEMS, etc.) and/or connections (e.g., wires, RDLs, TSVs, etc.) embedded therein or deposited thereon.

FIG. 3A shows the smaller component 306A bonded to the larger component 301A within the intended bonding region 310. In this sense, the smaller component 306A is properly aligned on the larger component 301A.

As noted, the bonded structure 300 includes the alignment guide regions 320, which are shown in more detail in side-sectional view in FIGS. 3B and 3C. Whereas the rest of the bond interface between the larger component 301A and smaller component 306A can be flat and smooth other than slightly recessed and protruding electrical contacts (as described, for example, in the descriptions of FIGS. 1A and 1B), the alignment guide regions 320 include more significantly protruding and recessed features (e.g., key and hole) that help guide the alignment of the components to be bonded.

FIG. 3A provides a nonlimiting example of a bonded structure, according to embodiments. FIG. 3A shows one smaller component 306A bonded to the larger component 301A. In some embodiments, a plurality of smaller components are bonded to the same larger component. FIG. 3A shows four alignment guide regions 320 within the intended bonding region 310. In some embodiments, fewer than four alignment guide regions are present within an intended bonding region. In some embodiments, one alignment guide region is present within an intended bonding region. In some embodiments, more than four alignment guide regions are present within an intended bonding region. FIG. 3A shows the alignment guide regions 320 near the periphery of the intended bonding region 310. In some embodiments, one or more alignment guide regions are present closer to the center of an intended bonding region.

FIGS. 3B and 3C depict side-sectional views of alignment guide regions 320B, 320C, according to some embodiments. Although not shown, it will be understood that the bonding surfaces will also include contacts prepared for hybrid bonding as described above with respect to FIGS. 1A and 1B. Alignment guide regions 320B and 320C are examples of alignment guide regions, such as alignment guide regions 320 shown in FIG. 3A. One of the components (e.g., either the larger component 301A or the smaller component 306A) comprises a male feature 306. The other component comprises a female feature 301. The male feature 306 comprises a protrusion 330 that fits into a cavity 340 of the female feature 301.

The male feature 306 comprises a protrusion 330. The protrusion extends beyond the surface of the rest of the male feature 306 by a protrusion height 332. The protrusion has a width (e.g., a radius or a lateral dimension) 334. In some embodiments, the protrusion 330 comprises an electrically conductive material, such as copper or aluminum. In some embodiments, the protrusion 330 comprises an electrically non-conductive material, such as a dielectric, e.g., silicon oxide.

The female feature 301 comprises a cavity 340. The cavity 340 has a depth below the surface of the rest of the female feature 301 by a depth 342. The cavity 340 has a width (e.g., a radius or a lateral dimension) 344. In some embodiments, the protrusion 330 of the male feature 306 can fit completely within the cavity 340 of the female feature 301. This means that, in some embodiments, the depth 342 of the cavity 340 is greater than the protrusion height 332 of the protrusion 330. For hybrid bonding embodiments, the differential between the depth 342 and height 332 can be greater than or equal to the gap between conductors prior to anneal. Additionally, in some embodiments, the width 344 of the cavity 340 is greater than the width 334 of the protrusion 330.

It will be understood by a skilled artisan that the male feature 306 can be part of the larger component 301A or the smaller component 306A. Similarly, the female feature 301 can be part of the other component—either the smaller component 306A or the larger component 301A.

The male feature 306 and female feature 301 can be embedded within the components (e.g., larger component 301A or the smaller component 306A). The female feature 301 comprises a dielectric 305. The dielectric 305 can comprise, for example, silicon oxide. The dielectric 305 can be part of a bonding layer configured to facilitate direct bonding to the opposite component. The layer of dielectric 305 can be similar to bonding layers 108a, 108b of FIGS. 1A and 1B. Correspondingly, the male feature 306 comprises a dielectric 308, which can be similar to the dielectric 305 of the female feature 301. The female feature 301 shown in FIGS. 3B and 3C can also include a metallization layer 303 (e.g., RDL or BEOL). In some embodiments, the male feature 306 includes a metallization layer 311 (e.g., BEOL or RDL, as shown in FIG. 4). In some embodiments, both the female feature 301 and the male feature 306 are shown to include a metallization layer 303 or 311 (as shown in FIG. 4).

As discussed above, FIGS. 3B and 3C share many similarities. A difference between FIGS. 3B and 3C is the depth 342 and nature of the cavity 340 of the female feature 301. In FIG. 3B, the cavity 340 is formed by providing recessing in a feature from the bonding surface, particularly by providing a recess over a conductive pad 302. Advantageously, the shallower cavity 340 formed over a conductive pad 302 can be provided by processing (e.g., wet etch) through a separate mask, or by providing a larger surface for the conductive pad 302 compared to adjacent pads that will participate in hybrid bonding, such that a common CMP process will dish the conductive pad 302 to a greater degree. In FIG. 3C, the cavity 340 extends to the metallization layer 303 with no conductive pad. The cavity 340 shown in FIG. 3B can have a depth 342 of between approximately 50 nm and 700 nm, between approximately 100 nm and 600 nm, between approximately 200 nm and 500 nm, or between approximately 300 nm and 400 nm. The cavity 340 shown in FIG. 3C can have a depth 342 of between approximately 500 nm and 10 microns, between approximately 900 nm and 5 microns, between approximately 900 nm and 2 microns, or between approximately 1 micron and 2 microns. The cavity 340 can have a depth 342 up to the thickness of the dielectric layer 305 (see FIG. 3C). For the embodiment of FIG. 3C, the cavity 340 can be provided by selectively wet etching a sacrificial feature, like a copper feature formed simultaneously with adjacent metal contacts for hybrid bonding, or can be formed by dry etching the dielectric 305 through a mask.

The protrusion height 332 is desirably less than the cavity depth 342. The difference between the cavity depth 342 and the protrusion height 332 can be between approximately 50 nm and 1.5 microns, between approximately 100 nm and 1 micron, between approximately 100 nm and 800 nm, or between approximately 200 nm and 500 nm. Desirably, the protrusion thickness 332 is large enough to prevent slipping beyond the width differential of the cavity 340 and protrusion 330. Said differently, if the protrusion 330 is too short, then slippage of the male feature 306 relative to the female feature 301 could cause the protrusion 330 to disadvantageously lift out of the cavity 340 and slide undesirably.

FIG. 4 shows an alignment guide region 420 with a male feature 306 and a female feature 301 before being bonded together. The male feature 306 can be part of a first integrated component (e.g., a component like the larger component 301A of FIG. 3A or the smaller component 306A of FIG. 3A). The female feature 301 can be part of a second integrated component configured to be bonded to the first integrated component. Although not shown, it will be understood that the bonding surfaces of the components will also include contacts prepared for hybrid bonding as described above with respect to FIGS. 1A and 1B. The female feature 301 of FIG. 4 is similar to the female feature 301 of FIG. 3C, in that the cavity 340 of the female feature 301 extends through the entire layer of dielectric 305 to the metallization layer 303. The male feature 306 comprises a protrusion 330 that extends through the entire layer of dielectric 308 to a metallization layer 311. In some embodiments, a protrusion does not extend through the entire layer of dielectric 308. In some embodiments, a protrusion is deposited or otherwise attached to the surface of the layer of dielectric 308.

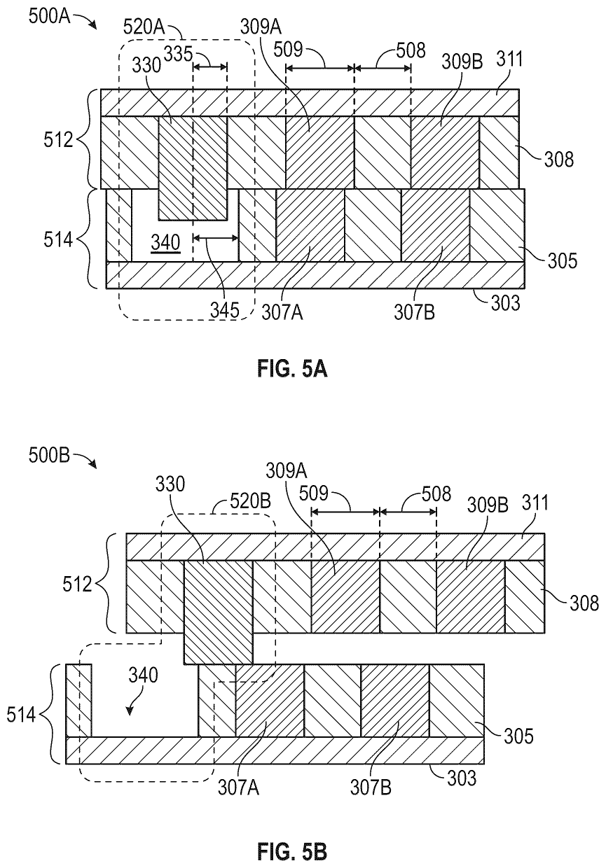

In FIG. 4, the protrusion 330 of the male feature 306 has a half-width (e.g., a radius) 335. The cavity 340 of the female feature 301 has a half-width (e.g., a radius) 345. Desirably, the half-width 335 of the protrusion 330 is less than the half-width 345 of the cavity 340, to allow the protrusion 330 to fit within the cavity 340. The difference between the half-width 345 of the cavity 340 and the half-width 335 of the protrusion 330 is the acceptable tolerance 348 of the alignment guide region 420. The acceptable tolerance 348 of the alignment guide region 420 can be designed to improve connection quality and yield of bonded structures, as shown, for example, FIGS. 5A-5B.

FIG. 5A shows a bonded structure 500A in which a first component 512 is direct bonded to a second component 514. FIG. 5B shows a bonded structure 500B in which the first component 512 is grossly misaligned with the second component 514. The first component 512 comprises a plurality of conductive features 309A, 309B (e.g., conductive pads) embedded in a layer of dielectric 308. The conductive features 309A, 309B can be similar to conductive features 106a, 106b shown in FIGS. 1A and 1B. The layer of dielectric 308 can comprise a bonding layer, the surface of which can be treated (e.g. planarized, activated and/or terminated) to facilitate direct bonding. It will be understood by a skilled artisan that the conductive features 309A, 309B and layer of dielectric 308 can be deposited or otherwise formed over the metallization layer 311, which in turn can be integrated within a larger device that can comprise, for example, a semiconductor substrate and other integrated electrical or mechanical components (not shown). The second component 514 comprises a plurality of conductive features 307A, 307B embedded in a layer of dielectric 305. The layer of dielectric 305 can comprise a bonding layer, the surface of which can be treated (e.g., planarized, activated, and/or terminated) to facilitate direct bonding. It will be understood by a skilled artisan that the conductive features 307A, 307B and layer of dielectric 305 can be deposited or otherwise formed over the metallization layer 303, which in turn can be integrated within a larger device that can comprise, for example, a semiconductor substrate and other integrated electrical or mechanical components (not shown). It will also be appreciated that, while both dielectric layers 308, 305 can be planarized for direct bonding, one or both of the surfaces can be additionally activated and/or terminated to strengthen bond energy.

The conductive features 309A, 309B of the first component 512 are configured to align with the conductive features 307A, 307B of the second component 514. Desirably, a first conductive feature 309A of the first component 512 is configured to align with a first conductive feature 307A of the second component 514, and a second conductive feature 309B of the first component 512 is configured to align with a second conductive feature 307B of the second component 514. The conductive feature 309A has a width 509. The other conductive features 309B, 307A, 307B can have a width similar to the width 509 of the conductive feature 309A. The conductive features 309A, 309B are separated by a spacing 508.

The bonded structures 500A and 500B each have an alignment guide region 520A, 520B, respectively. Beneficially, the alignment guide region 520A, 520B can help improve connection quality and yield of bonded structures. Within the alignment guide region 520A, 520B, the first component 512 has a protrusion 330 with a protrusion half-width 335. Within the alignment guide region 520A, 520B, the second component 514 has a cavity 340 with a cavity half-width 345. As shown in FIG. 4, the difference between the half-width 345 of the cavity 340 and the half-width 335 of the protrusion 330 is the acceptable tolerance 348 of the alignment guide region 420.

The acceptable tolerance 348 of the alignment guide region 520A, 520B can be designed to improve connection quality and yield of bonded structures. Desirably, the acceptable tolerance 348 of an alignment guide region 520A, 520B can less than (1) the width 509 of conductive features 309A, 309B to be aligned and also less than (2) the width 508 of dielectric 308 separating adjacent conductive features 309A, 309B. However, the skilled artisan will appreciate that this need not be the case in some embodiments, as further described below.

The components (e.g., 512, 514) bonded to form the bonded structure 500A shown in FIG. 5A are not perfectly aligned, but they are aligned within the acceptable tolerance 348. The protrusion 330 is not perfectly centered within the cavity 340, but the protrusion 330 is still aligned such that it fits within the cavity 340. Desirably, the first conductive feature 309A of the first component 512 is aligned with the first conductive feature 307A of the second component 514, and the second conductive feature 309B of the first component 512 is aligned with the second conductive feature 307B of the second component 514.

The components configured to form the intended bonded structure 500B shown in FIG. 5B are so grossly misaligned that the protrusion 330 of the first component 512 does not align with or fit within the cavity 340 of the second component 514. These two components are not aligned within the acceptable tolerance 348.

The protrusion-cavity system shown in FIGS. 5A and 5B has various benefits if the alignment guide regions 520A and 520B are less than (1) the width 509 of conductive features 309A, 309B to be aligned and also less than (2) the width 508 of dielectric 308 separating adjacent conductive features 309A, 309B. One benefit of such a system is that if one component is placed onto the other (e.g., by a pick-and-place apparatus) within the acceptable tolerance 348 of the alignment guide region 520A (as shown in FIG. 5A), the components will be prevented from slipping out of alignment by the protrusion 330 inside the cavity 340. Even if one die slides relative to the other such that the protrusion 330 contacts a side edge of the cavity 340, the bonded structure would still be aligned within acceptable tolerance 348 in some embodiments. All conductive features 309A, 309B, 307A, 307B would remain aligned well enough.

Another benefit of such a system is that if one component is placed onto the other (e.g., by a pick-and-place apparatus) outside the acceptable tolerance 348 (as shown in FIG. 5B), the first and second components may not bond. If the dielectrics 305, 308 do not contact each other across significant flush surfaces (as shown in FIG. 5B), the first component 512 may not bond to the second component 514. The picked and placed component 512 can be readily lifted since a strong bond has not formed, and if needed the component can be re-processed, and placement and bonding can be retried. Said differently, beneficially, in such a system, if a bond is formed between two components, the protrusion-cavity system improves the likelihood that the features of the two components (e.g., conductive features 307A, 307B, 309A, 309B) are properly aligned. Meanwhile, if the two components are so grossly misaligned when placed that the protrusion 330 and cavity 340 do not engage, a strong likelihood exists that the components will not bond out of alignment, and the placement and bonding can be retried.

An example helps illustrate how to design a protrusion and cavity to help ensure alignment between features (e.g., conductive features). Assume the conductive feature 309A has a width 509 of 10 microns, and the spacing 508 separating conductive features 309A, 309B is also 10 microns. Also assume the width 334 of the protrusion 330 is 20 microns (i.e., the half-width 335 of the protrusion 330 is 10 microns). The theoretical maximum for the acceptable tolerance 348 to ensure proper alignment—being the lesser of widths 508 and 509—is 10 microns. This means the cavity 340 can desirably be designed to have a half-width 345 of 20 microns (the sum of the protrusion half-width 335 and the acceptable tolerance 348). The cavity 340, therefore, can be designed to desirably have a maximum width 344 of 40 microns. The 40-micron cavity width 344 corresponds to having an acceptable tolerance 348 that is 100% of the theoretical maximum to ensure proper alignment. In some embodiments, the acceptable tolerance 348 can be between approximately 10% and 90% of the theoretical maximum, between approximately 25% and 85% of the theoretical maximum, between 50% and 85% of the theoretical maximum, between 75% and 85% of the theoretical maximum, or approximately 80% of the theoretical maximum. In this example, a cavity 340 with 80% of the theoretical maximum acceptable tolerance 348 would have an acceptable tolerance of 8 microns. Such a cavity would have a half-width of 18 microns and a full width of 36 microns.

The discussion of FIGS. 5A and 5B and the above example relate to embodiments in which the protrusions 330 and cavities 340 are designed to have an acceptable tolerance 348 configured to keep features (e.g., conductive features 307A, 307B, 309A, 309B) sufficiently aligned. In some embodiments, however, the protrusions and cavities can be designed and formed with a tolerance unrelated to the widths of features (e.g., width 509 of conductive feature 309A) or the widths of dielectric separating features (e.g., width 508 of dielectric 308 separating conductive features 309A and 309B). In some embodiments, engagement of the protrusion 330 with the cavity 340 may prevent the components from interfering with neighboring components or bonding sites, even if the misalignment prevents electrical connections of the conductive features 307A/309A, 307B/309B. Even where the components 512, 514 fail to electrically connect, the engagement of the protrusion 330 with the cavity 340 can advantageously limit the yield loss to the single misaligned die, without affecting neighboring dies. Accordingly, the tolerance for engagement of the protrusions and cavities may be beyond the tolerance for connection of the conductive features 307A/309A, 307B/309B.

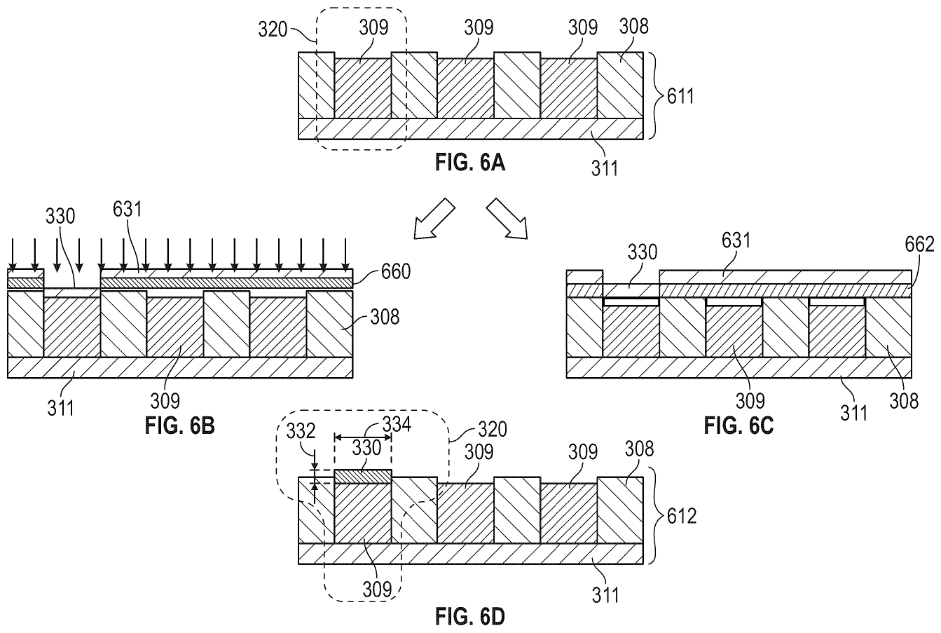

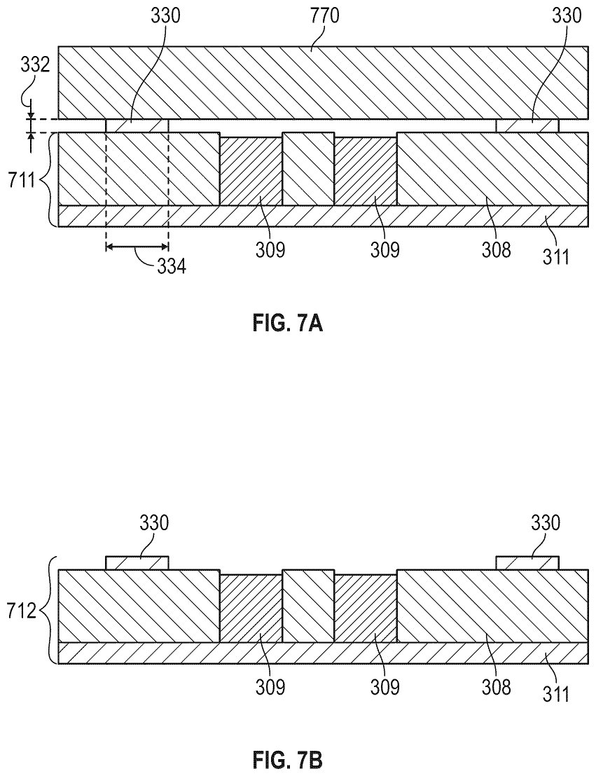

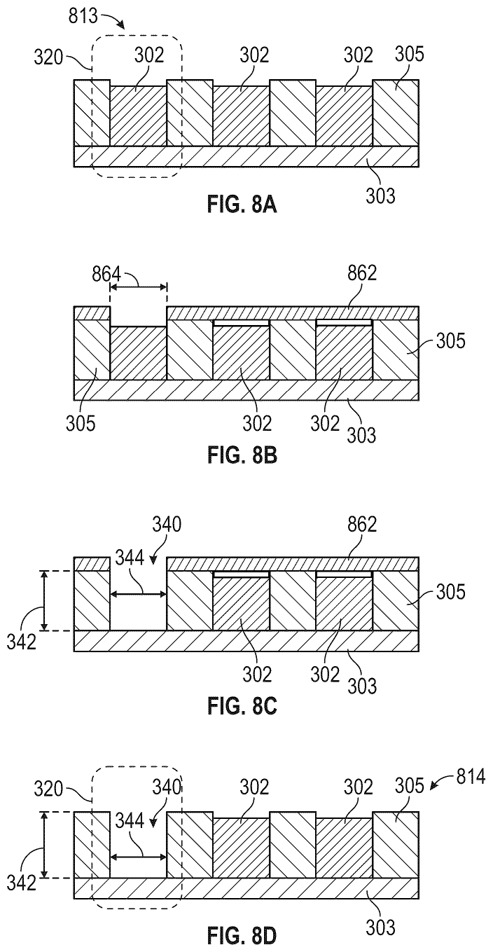

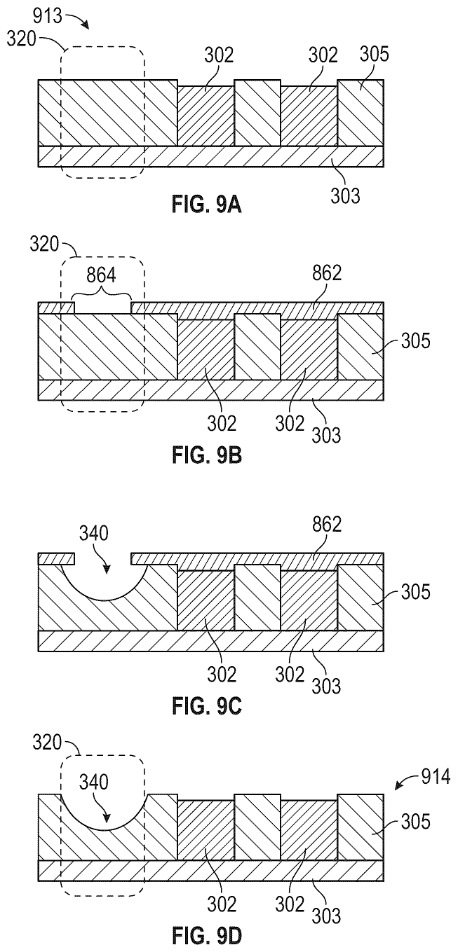

FIGS. 6A-9D show example methods of forming protrusions or cavities. FIGS. 6A-7B show methods of forming protrusions. FIGS. 8A-9D show methods of forming cavities.

FIGS. 6A-6D show methods of forming a protrusion 330 by a deposition process. FIG. 6A shows microelectronic component 611 with a layer of dielectric 308 on a metallization layer 311 (e.g., BEOL or RDL), and conductive features 309 embedded within the layer of dielectric 308. A portion of the microelectronic component 611 is an alignment guide region 320, which is configured to have a protrusion 330 deposited thereon. The formation of the microelectronic component 611 shown in FIG. 6A can be a conventional formation of a bonding layer for direct bonding, as shown in FIGS. 1A-1B. The surface of the dielectric 308 and conductive features 309 can already have been at least partially prepared for direct bonding, for example by planarization for very low roughness on the surface of the dielectric, and is shown with the conductive features 309 slightly recessed relative to the layer of dielectric 308. The surface can also be activated and/or terminated prior to or after forming the protrusion 330.

FIGS. 6B and 6C show different techniques for depositing the material of protrusion 330. In FIG. 6B, protrusion material 631 is deposited through a shadow mask 660, for example, by a physical vapor deposition (PVD) process. In FIG. 6C, protrusion material 631 is deposited over a patterned layer of resist 662. After the protrusion material 631 is deposited, such as by PVD or electroless deposition, the material deposited on the resist can be removed by a lift-off process during removal of the resist, leaving protrusion 330.

The different processes shown in FIGS. 6B and 6C are better suited to form different sizes of protrusions. The shadow mask method of FIG. 6B is well-suited for depositing protrusions with dimensions (e.g., width or diameter) of greater than, for example, 5 microns. The lift-off method of FIG. 6C is well-suited for depositing a protrusion with dimensions of less than, for example, 5 microns.

The different processes shown in FIGS. 6B and 6C can form protrusions of different material compositions. Protrusions formed using PVD method in either embodiment can be formed by materials that readily evaporate, such as copper, aluminum, gold, or the like. Alternatively, sputtering types of PVD can be used to deposit a great variety of materials. Protrusions formed using the lift-off method of FIG. 6C can be formed using PVD but can also be formed by other methods, such as electroless deposition. Either method can be employed to deposit conductive (e.g., metallic) or dielectric (e.g., silicon oxide, silicon nitride) materials.

FIG. 6D shows a resulting microelectronic component 612 with a protrusion 330 deposited formed in the alignment guide region 320 of a microelectronic component. FIG. 6D shows the structure of FIG. 6B after removal of the shadow mask 660 and any protrusion material 631 deposited over the shadow mask 660. Alternatively, FIG. 6D shows the structure of FIG. 6C after removal of the layer of photoresist 662 and any protrusion material 631 deposited over the layer of photoresist 662. The protrusion 330 has a protrusion height 332 and a protrusion width 334 (e.g., a diameter or other lateral dimension). In some embodiments, the conductive features 309 that have an exposed surface (e.g., the conductive features 309 that do not have a protrusion 330 thereon) are hybrid bonding pads.

In the structure of FIG. 6D, the protrusion 330 is over a conductive feature 309. In some embodiments, a protrusion can be over only a portion of a conductive feature. In some embodiments, a protrusion can be over a portion of the layer of dielectric (e.g., dielectric 308). In some embodiments, a protrusion can be over a combination of dielectric and conductive feature.

FIGS. 7A-7B show an alternative process for forming a protrusion on a microelectronic component 711, in which a protrusion is transferred from a carrier die or wafer (e.g., carrier 770). FIG. 7A shows a microelectronic component 711 direct bonded to such a carrier 770 on which the protrusions 330 have been formed. The microelectronic component 711 is similar to the structure shown in FIG. 6A, with a metallization layer 311, conductive features 309, and layer of dielectric 308. The carrier 770 has one or more protrusions 330 mounted or formed thereon, with a protrusion width 334 and protrusion height 332. The surfaces of the protrusions that face the microelectronic component 711 can comprise a nonconductive material, such as a dielectric, for example, an oxide such as silicon oxide. The protrusion(s) 330 can be passive posts or in other arrangements can comprise active or passive devices, such as thin profile optical or MEMS components.

FIG. 7B shows the structure of FIG. 7A after the carrier 770 has been removed. The resulting structure 712 is the microelectronic component 711 with protrusions 330 that were transferred from the carrier 770, rather than deposited (e.g., as shown in FIGS. 6A-6D). Beneficially, the process shown in FIGS. 7A-7B can be cleaner than the process shown in FIGS. 6A-6D, at least in part because, outside of the region of the protrusions 330, the bonding surface (e.g., the exposed surfaces of the conductive features 309 and surrounding dielectric 308) is not touched, for example, by a mask or photoresist. The process shown in FIGS. 7A-7B of transferring protrusions 330 from a carrier 770 to a microelectronic component 711 can work effectively to transfer protrusions 330 that have a width 334 of at least approximately 10 microns.

In FIGS. 7A-7B, two protrusions 330 are transferred from a carrier 770 to the surface of the dielectric 308. In some embodiments, one protrusion is transferred. In some embodiments, more than two protrusions are transferred. In some embodiments, one or more protrusions are transferred to the surface of a conductive feature 309.

FIGS. 8A-8D show a process of forming a cavity by selectively etching a conductive feature. FIG. 8A shows a microelectronic component 813 similar to the structure shown in FIG. 6A. FIG. 8A depicts a metallization layer 303 (e.g., BEOL or RDL), conductive features 302, and layer of dielectric 305 that are similar to the metallization layer 311, conductive features 309, and layer of dielectric 305 shown in FIG. 6A. Also like in FIG. 6A, FIG. 8A depicts an alignment guide region 320, where a cavity will be formed. The conductive feature 302 within the alignment guide region 320 will be etched or otherwise removed in part or in full (as shown in FIGS. 8C-8D). In some embodiments, the conductive feature 302 within the alignment guide region 320 comprises copper or another material that can be selectively wet etched. The conductive features 302 that are not within the alignment guide region 320 can be hybrid bonding pads, similar to conductive features 106a, 106b in FIGS. 1A-1B, and are shown slightly recessed relative to the layer of dielectric 305.

The exposed surface of the conductive features 302 and dielectric 305 in FIG. 8A can be prepared for dielectric bonding (e.g., already smoothed by a CMP process and sufficiently planarized for hybrid bonding). In some embodiments, the exposed surface is not yet prepared for direct bonding. In such embodiments, the surface is prepared for dielectric bonding after photoresist is stripped (as shown in FIG. 8D).

In FIG. 8B, a temporary layer 862 is patterned over the surface of microelectronic component 813, leaving an opening 864 in the alignment guide region 320. The temporary layer 862 can comprise photoresist or other mask material. In FIG. 8B, the opening 864 corresponds to a full width of a conductive feature 302. In some embodiments, the opening 864 can be narrower than the width of a conductive feature. For example, the temporary layer 862 can be deposited over a portion of the conductive feature 302 otherwise exposed by the opening 864.

FIG. 8C shows the formation of a cavity 340 through the opening 864 in the temporary layer 862. The cavity 340 can be formed by a reactive-ion etch (RIE). Advantageously, because the cavity 340 is formed by removing a pre-existing feature that has different material from the surrounding layer of dielectric 305, the cavity 340 can be formed by a wet etch, e.g., a selective wet etch. Beneficially, a wet etch is less costly and can leave the temporary layer 862 easy to remove. Although the feature need not be a conductive material to facilitate the selective removal, it is less costly to form the feature at the same time as forming other conductive features 309 for hybrid bonding. The cavity has a cavity width 344 and a cavity depth 342.

In FIG. 8C, the cavity 340 is shown as formed by fully removing the conductive feature 302 within the alignment guide region 320. However, the cavity 340 can be a different depth. For example, only a portion of the depth of the exposed conductive feature 302 can be etched, leaving a shallower cavity, as shown in FIG. 3B. As described herein, cavity 340 is configured to align with a protrusion (such as the protrusion 330 of FIG. 6D or 7B) of a component to be directly bonded to the microelectronic component 813. As such, the cavity width 344 is desirably greater than the width of the protrusion and cavity depth 342 is desirably greater than the height of the protrusion with which the cavity 340 is configured to align.

FIG. 8D shows a microelectronic structure 814, which is the structure of FIG. 8C after the temporary layer 862 has been removed. In some embodiments, removing the temporary layer 862 comprises stripping photoresist. As mentioned above, if the exposed surface of the microelectronic component 813 was not prepared for direct bonding before deposition of the temporary layer 862, then the exposed surface of the microelectronic component 814 can be prepared (or further prepared) for direct bonding after the temporary layer 862 is removed.

FIGS. 9A-9D show a process of forming a cavity by etching the surface of the dielectric 305. The component 913 shown in FIG. 9A is similar to the component 813 shown in FIG. 8A, except that in FIG. 9A, there is no conductive feature in the alignment guide region 320. FIG. 9B is similar to FIG. 8B, wherein a temporary layer 862 is patterned over the surface of conductive features 302 and dielectric 305, leaving an opening 864 within the alignment guide region 320.

FIG. 9C shows the structure of FIG. 9B after a cavity 340 is formed (e.g., etched) from the opening 864 in the temporary layer 864. The cavity 340 can be formed by RIE if vertical sidewalls are desired, but is shown as the result of an isotropic etch process (e.g., a wet etch or dry etch) of the dielectric 305. The depth and width of the cavity 340 can be controlled, for example, by the duration of the etch. The cavity 340 need not extend all the way down to the metallization layer 303. As disclosed herein, cavity 340 is desirably wider than the width of the protrusion deeper than the height of the protrusion with which the cavity 340 is configured to align.

The cavity 340 shown in FIG. 9C is rounded. Beneficially, a cavity 340 that is rounded (e.g., curved or with rounded corners) can passively self-center a protrusion from a different component.

FIG. 9D shows the resulting component 914, which is the structure of FIG. 9C after the temporary layer 862 has been removed. As disclosed herein, if the exposed surface of the microelectronic component 913 was not prepared for direct bonding before deposition of the temporary layer 862, then the exposed surface of the microelectronic component 914 can be prepared for direct bonding after the temporary layer 862 is removed.

In one aspect, a bonded structure includes a first microelectronic structure and a second microelectronic structure. The first microelectronic structure includes a first bonding surface and at least one cavity through the first bonding surface. The second microelectronic structure includes a second bonding surface directly bonded to the first bonding surface and at least one protrusion extending above the second bonding surface. The at least one protrusion of the second microelectronic structure extends within the at least one cavity of the first microelectronic structure without reaching a bottom of the at least one cavity.

In some embodiments, the second bonding surface is hybrid bonded to the first bonding surface. In some embodiments, the at least one cavity of the first microelectronic structure has a cavity width, and the at least one protrusion of the second microelectronic structure has a protrusion width less than the cavity width. In some embodiments, the cavity width is greater than the protrusion width by about 5-20 μm. In some embodiments, half of the cavity width is about 120% to 300% of half of the protrusion width. In some embodiments, the first electronic structure has a first footprint, and the second electronic structure has a second footprint smaller than the first footprint. In some embodiments, the first electronic structure has a first footprint, and the second electronic structure has a second footprint larger than the first footprint. In some embodiments, the at least one protrusion is integrally formed with the second microelectronic structure. In some embodiments, the first microelectronic structure comprises a semiconductor wafer. In some embodiments, the second microelectronic structure comprises an integrated circuit die. In some embodiments, the first microelectronic structure comprises an integrated circuit die. In some embodiments, the second microelectronic structure comprises a semiconductor wafer.

In another aspect, a bonded structure includes a first microelectronic structure and a second microelectronic structure. The first microelectronic structure includes a first bonding surface, a plurality of conductive features embedded within the first bonding surface, and at least one cavity through the first bonding surface. The second microelectronic structure includes a second bonding surface directly bonded to the first bonding surface, a plurality of conductive features embedded within the second bonding surface and directly bonded to the plurality of conductive features of the first microelectronic structure, and at least one protrusion extending above the second bonding surface. The at least one protrusion of the second microelectronic structure extends within the at least one cavity of the first microelectronic structure without reaching a bottom of the at least one cavity.

In some embodiments, the second bonding surface is hybrid bonded to the first bonding surface. In some embodiments, an acceptable tolerance is defined by the difference between a half-width of the cavity and a half-width of the protrusion, and a width of a conductive feature from among the pluralities of conductive features is greater than the acceptable tolerance. In some embodiments, each conductive feature is laterally spaced from an adjacent conductive feature by a spacing width, and the spacing width is greater than the acceptable tolerance.

In another aspect, a method of forming a bonded structure is provided. The method includes providing a first microelectronic structure. The first microelectronic structure includes a first bonding surface and at least one cavity through the first bonding surface. The method also includes providing a second microelectronic structure. The second microelectronic structure includes a second bonding surface and at least one protrusion extending above the second bonding surface. The method also includes directly bonding the bonding surface of the first microelectronic structure to the bonding surface of the second microelectronic structure, such that the at least one protrusion of the second microelectronic structure extends within the at least one cavity of the first microelectronic structure without reaching a bottom of the at least one cavity.

In some embodiments, the method also includes forming the at least one protrusion by a deposition process. In some embodiments, the method also includes forming the at least one protrusion by transferring the protrusion from a carrier onto the second microelectronic structure. In some embodiments, the method also includes forming the at least one cavity by a selective wet etch of a conductive feature. In some embodiments, the method also includes forming the at least one cavity by an isotropic etch process of a dielectric material.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Moreover, as used herein, when a first element is described as being “on” or “over” a second element, the first element may be directly on or over the second element, such that the first and second elements directly contact, or the first element may be indirectly on or over the second element such that one or more elements intervene between the first and second elements. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

What is claimed is:

1. A bonded structure comprising:
a first microelectronic structure comprising:
a first bonding surface; and
at least one cavity through the first bonding surface; and
a second microelectronic structure comprising:
a second bonding surface directly bonded to the first bonding surface; and
at least one protrusion extending above the second bonding surface,
wherein the at least one protrusion of the second microelectronic structure extends within the at least one cavity of the first microelectronic structure without reaching a bottom of the at least one cavity.

2. The bonded structure of claim 1, wherein the second bonding surface is hybrid bonded to the first bonding surface.

3. The bonded structure of claim 1, wherein the at least one cavity of the first microelectronic structure has a cavity width, and wherein the at least one protrusion of the second microelectronic structure has a protrusion width less than the cavity width.

4. The bonded structure of claim 3, wherein the cavity width is greater than the protrusion width by about 5-20 μm.

5. The bonded structure of claim 3, wherein half of the cavity width is about 120% to 300% of half of the protrusion width.

6. The bonded structure of claim 1, wherein the first electronic structure has a first footprint, and wherein the second electronic structure has a second footprint smaller than the first footprint.

7. The bonded structure of claim 1, wherein the first electronic structure has a first footprint, and wherein the second electronic structure has a second footprint larger than the first footprint.

8. The bonded structure of claim 1, wherein the at least one protrusion is integrally formed with the second microelectronic structure.

9. The bonded structure of claim 1, wherein the first microelectronic structure comprises a semiconductor wafer.

10. The bonded structure of claim 9, wherein the second microelectronic structure comprises an integrated circuit die.

11. The bonded structure of claim 1, wherein the first microelectronic structure comprises an integrated circuit die.

12. The bonded structure of claim 11, wherein the second microelectronic structure comprises a semiconductor wafer.

13. A bonded structure comprising:
a first microelectronic structure comprising:
a first bonding surface,
a plurality of conductive features embedded within the first bonding surface, and
at least one cavity through the first bonding surface; and
a second microelectronic structure comprising:
a second bonding surface directly bonded to the first bonding surface,
a plurality of conductive features embedded within the second bonding surface and directly bonded to the plurality of conductive features of the first microelectronic structure, and
at least one protrusion extending above the second bonding surface,
wherein the at least one protrusion of the second microelectronic structure extends within the at least one cavity of the first microelectronic structure without reaching a bottom of the at least one cavity.

14. The bonded structure of claim 13, wherein the second bonding surface is hybrid bonded to the first bonding surface.

15. The bonded structure of claim 13, wherein an acceptable tolerance is defined by the difference between a half-width of the cavity and a half-width of the protrusion, and
wherein a width of a conductive feature from among the pluralities of conductive features is greater than the acceptable tolerance.

16. The bonded structure of claim 15, wherein each conductive feature is laterally spaced from an adjacent conductive feature by a spacing width, and the spacing width is greater than the acceptable tolerance.

17. A method of forming a bonded structure, the method comprising:
providing a first microelectronic structure, the first microelectronic structure comprising:
a first bonding surface, and
at least one cavity through the first bonding surface;
providing a second microelectronic structure, the second microelectronic structure comprising:
a second bonding surface, and
at least one protrusion extending above the second bonding surface;
directly bonding the bonding surface of the first microelectronic structure to the bonding surface of the second microelectronic structure, such that the at least one protrusion of the second microelectronic structure extends within the at least one cavity of the first microelectronic structure without reaching a bottom of the at least one cavity.

18. The method of claim 17, further comprising forming the at least one protrusion by a deposition process.

19. The method of claim 17, further comprising forming the at least one protrusion by transferring the protrusion from a carrier onto the second microelectronic structure.

20. The method of claim 17, further comprising forming the at least one cavity by a selective wet etch of a conductive feature.

21. The method of claim 17, further comprising forming the at least one cavity by an isotropic etch process of a dielectric material.
